(19) United States
(12) Patent Application Publication
(10) Pub. No.: US 2024/0347485 A1
(43) Pub. Date: Oct. 17, 2024

(54) MICROWAVE INTEGRATED CIRCUIT AND MANUFACTURING METHOD OF THE SAME

(71) Applicant: XIAMEN SAN'AN INTEGRATED CIRCUIT CO., LTD., Fujian (CN)

(72) Inventors: Shenghou LIU, Fujian (CN); Wei ZHAO, Fujian (CN); Zlichen WANG, Fujian (CN); Xiguo SUN, Fujian (CN)

(21) Appl. No.: 18/756,027

(22) Filed: Jun. 27, 2024

Related U.S. Application Data
(63) Continuation-in-part of application No. PCT/CN2022/118925, filed on Sep. 15, 2022.

(30) Foreign Application Priority Data
Dec. 28, 2021 (CN) 202111629639.2

(51) Int. Cl. H01L 23/66; H01L 23/522

(52) U.S. Cl. CPC H01L 23/66; H01L 23/5223; H01L 2223/6605; H01L 2223/6644

(57) ABSTRACT

A microwave integrated circuit includes a passive circuit and an active device. The passive circuit includes a base substrate and passive devices. The base substrate includes a first substrate, and defines an active region and a passive region. The active region is formed with reserved pins. The passive devices are disposed on the passive region. The active device includes a second substrate, an epitaxial layer, electrodes, and first conductive connectors disposed in the second substrate and the epitaxial layer. The first conductive connectors correspond in position to the electrodes for electrically connecting the electrodes to a back side of the active device. The electrodes are connected to the reserved pins in the active region via the first conductive connectors, respectively, to connect the back side of the active device to a front side of the passive circuit. A method for manufacturing the microwave integrated circuit is also provided.

### CROSS-REFERENCE TO RELATED APPLICATION

This application is a continuation-in-part (CIP) of International Application No. PCT/CN2022/118925, filed on Sep. 15, 2022, which claims priority to Chinese Invention Patent Application No 202111629639.2, filed on Dec. 28, 2021. The aforesaid applications are incorporated by reference herein in their entirety.

### FIELD

The disclosure relates to the field of semiconductors, and more particularly to a microwave integrated circuit and a manufacturing method of the same.

### BACKGROUND

Due to the requirements of miniaturization and high performance in radio frequency applications such as microwave backhaul, small cells, microcells, and communication satellites, monolithic microwave integrated circuits (MMICs) of GaN-based power amplifiers have been widely used in the X-band or above.

The MMIC characteristically includes passive devices (e.g., capacitors, inductors, resistors, etc.) and active devices (e.g., GaN transistors) those are monolithically integrated on a chip, wherein the total area of the passive devices is greater than the total area of the active devices. That is, the passive devices and the active devices share the same substrate. Conventionally, the substrate being used needs to meet the performance requirements of the active devices, which requires a particular arrangement for the placements of the passive devices and the active devices on the entire substrate. Due to the passive devices of the MMIC occupying a large area on the substrate, unnecessary, high cost for such particular arrangement when manufacturing the MMIC is incurred.

### SUMMARY

Therefore, an object of the disclosure is to provide a microwave integrated circuit that can alleviate at least one of the drawbacks of the prior art.

According to an aspect of the disclosure, the microwave integrated circuit includes a passive circuit and at least one active device.

The passive circuit has a front side, and includes a base substrate and a plurality of passive devices. The base substrate includes a first substrate. The base substrate defines at least one active region and at least one passive region. The at least one active region is formed with a plurality of reserved pins. The passive devices are disposed on the at least one passive region.

The at least one active device has a back side, and includes a second substrate, an epitaxial layer and a plurality of electrodes disposed sequentially in such order in a bottom-top direction, and a plurality of first conductive connectors disposed in the second substrate and the epitaxial layer. The first conductive connectors correspond in position to the electrodes for electrically connecting the electrodes to the back side of the at least one active device.

The electrodes are connected to the reserved pins in the at least one active region via the first conductive connectors, respectively, so as to connect the back side of the at least one active device to the front side of the passive circuit.

According to another aspect of the disclosure, a method for manufacturing a microwave integrated circuit includes steps of:
forming a base substrate, the base substrate including a first substrate, the base substrate defining at least one active region and at least one passive region;
forming a plurality of passive devices on the at least one passive region of the base substrate, and forming a plurality of reserved pins on the at least one active region, thereby forming a passive circuit;
forming at least one active device by forming a second substrate, an epitaxial layer and a plurality of electrodes sequentially in such order in a bottom-top direction, and forming a plurality of first conductive connectors on the second substrate and the epitaxial layer, so as to electrically connect the electrodes to a back side of the at least one active device; and
connecting the electrodes of the at least one active device to the reserved pins via the first conductive connectors, respectively, so as to connect the back side of the at least one active device to a front side of the passive circuit.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic diagram of a conventional microwave integrated circuit.

FIG. 2 is a schematic diagram of a first embodiment of a microwave integrated circuit according to the disclosure, illustrating a passive circuit and an active device.

FIG. 3 is a schematic diagram of the first embodiment of the microwave integrated circuit, illustrating layers in the microwave integrated circuit.

FIG. 4 is a schematic diagram of the first embodiment of the microwave integrated circuit, illustrating the passive circuit and a partial enlarged view of an active region.

FIG. 5 is a flow chart illustrating a method for manufacturing the embodiment of the microwave integrated circuit.

FIG. 6 is a schematic diagram of the first embodiment of the microwave integrated circuit, illustrating layers in the passive circuit.

FIG. 7 is a schematic diagram of the first embodiment of the microwave integrated circuit, illustrating layers in the active device.

FIG. 8 is a schematic diagram of a second embodiment of a microwave integrated circuit, illustrating layers in the microwave integrated circuit.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

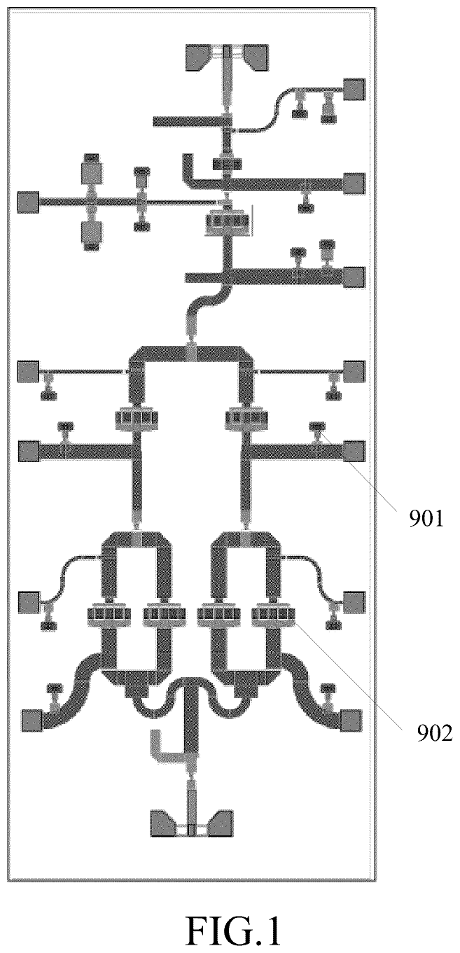

Referring to FIG. 1, a schematic diagram of a conventional microwave integrated circuit is shown, which includes a plurality of passive devices 901 and a plurality of active devices 902. The passive devices 901 include capacitors, inductors, and resistors. The active devices 902 include conventional GaN-based transistors. The passive devices 901 and the active devices 902 share a same substrate. Referring to FIG. 1, a total area of the passive devices 901 is greater than a total area of the active devices 902.

Currently in GaN-based radio frequency applications, a GaN-based transistor adopts a semi-insulating SiC substrate. Due to SiC material being more expensive, a manufacturing cost of the conventional microwave integrated circuit is higher. Unlike the GaN-based transistors, the passive devices 901 of the conventional microwave integrated circuit do not have specific requirements for the substrate as the GaN-based transistor. However, due to the passive devices 901 occupying a greater area on the shared SIC substrate compared to the active devices 902, the higher cost of the conventional microwave integrated circuit mainly derives from the passive devices 901. That is to say, an unnecessary cost is incurred.

As a result, an embodiment of a microwave integrated circuit according to the disclosure is provided, and includes a passive circuit and an active device. The passive circuit and the active device may each adopt a different material for a substrate, so that when the active device needs to adopt a certain substrate, a manufacturing cost of the microwave integrated circuit is not increased drastically due to passive devices of the passive circuit occupying a large space.

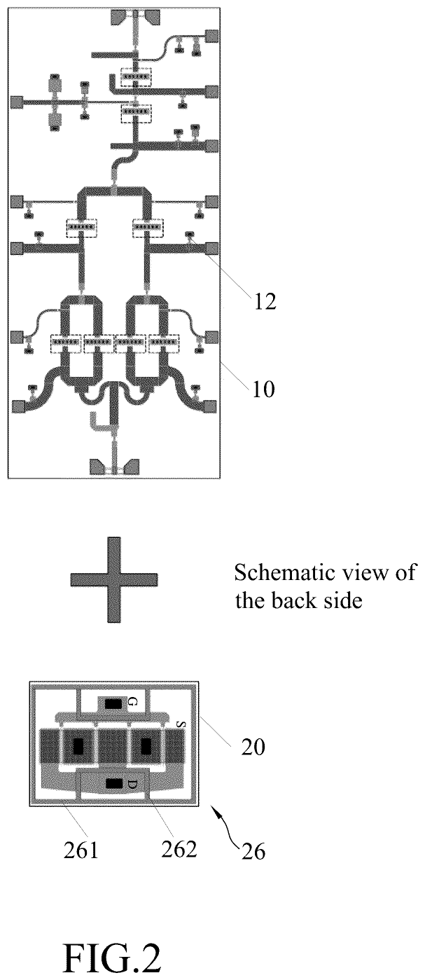

Referring to FIG. 2, a schematic diagram of a first embodiment of a microwave integrated circuit according to the disclosure is shown. The microwave integrated circuit includes a passive circuit 10 and at least one active device 20. In this embodiment, the microwave integrated circuit includes a plurality of active devices 20. For a brief explanation, the following will take an active device as an example to illustrate. The active device 20 has a front side and a back side. The passive circuit 10 has a front side and a back side, and includes a base substrate and a plurality of passive devices 12. The base substrate includes a first substrate 11, and defines at least one active region 101 and at least one passive region 102. The active device 20 is disposed in the active region 101 of the passive circuit 10, and the passive devices 12 are disposed in the passive region 102 of the passive circuit 10. In this embodiment, the active device 20 is a GaN-based transistor, and the passive devices 12 are capacitors, inductors, resistors, etc.

By virtue of soldering or bonding, such as copper pillar bumping or metal pad bonding, the back side of the active device 20 is connected to the front side of the passive circuit 10, thereby forming the microwave integrated circuit.

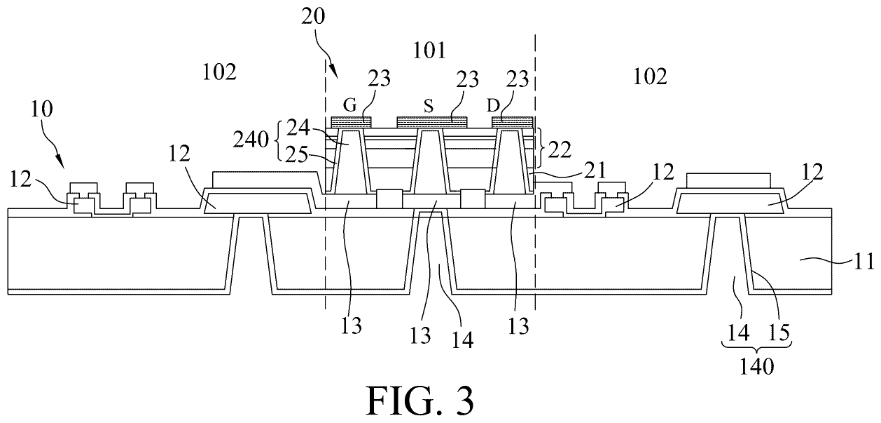

Referring to FIG. 3, the first substrate 11 includes a conventional epitaxial structure, which is not a focus of the present disclosure and therefore description thereof is omitted.

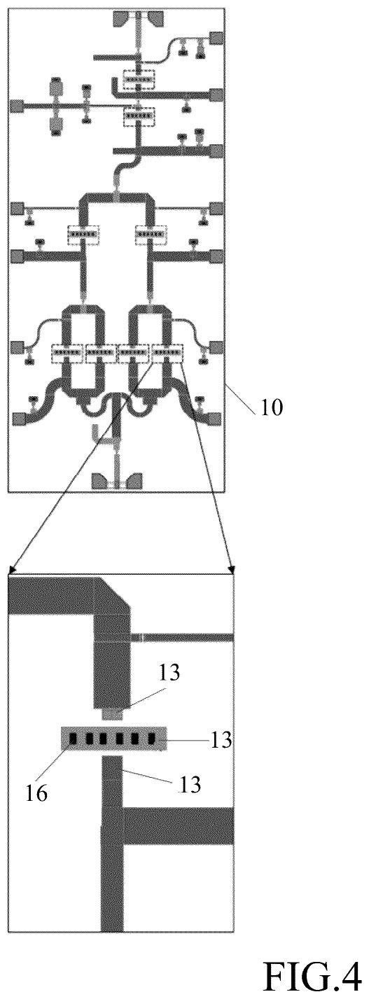

Referring to FIGS. 3 and 4, the active region 101 is formed with a plurality of reserved pins 13. The active device 20 includes a second substrate 21, an epitaxial layer 22, and a plurality of electrodes 23 disposed sequentially in such order a bottom-top direction. The electrodes 23 and the reserved pins 13 define the front side and backside of the active device 20, respectively.

The front side of the active device 20 is not a flat surface, and is not adapted for bearing pressure (i.e., pressure during packaging). Therefore, the front side of the active device 20 may not be connected to the front side of the passive circuit 10. As a result, in this embodiment, the active device 20 further includes a plurality of first conductive connectors 240 that are disposed in the second substrate 21 and the epitaxial layer 22 and that correspond in position to the electrodes 23 for electrically connecting the electrodes 23 to the back side of the active device 20, thereby connecting the back side of the active device 20 to the front side of the passive circuit 10. In addition, the front side of the active device 20 faces upward and has a protective film formed thereon.

In this embodiment, the electrodes 23 on the front side of the active device 20 are electrically connected to the back side of the active device 20 via the first conductive connectors 240. The first conductive connectors 240 may be formed by wire bonding or backside copper pillar bumping, but is not limited thereto, as long as the electrodes 23 may be electrically connected to the back side of the active device 20. For example, the wire bonding may be performed by ultrasonic welding.

In this embodiment, after the electrodes 23 of the active device 20 are electrically connected to the back side of the active device 20 via the first conductive connectors 240, the electrodes 23 are connected to the reserved pins 13 in the active region 101 via the first conductive connectors 240, respectively, by copper pillar bumping or metal pad bonding, thereby connecting the back side of the active device 20 to the front side of the passive circuit 10.

In this embodiment, the passive circuit 10 adopts the first substrate 11, and the active device 20 adopts the second substrate 21. The electrodes 23 of the active device 20 are electrically connected to the back side of the active device 20 via the first conductive connectors 240, thereby allowing the electrodes 23 to be connected to the reserved pins 13 on the passive circuit 10, so as to connect the back side of the active device 20 to the front side of the passive circuit 10, and the microwave integrated circuit is thus formed.

In the microwave integrated circuit, the active device 20 and the passive circuit 10 may adopt different substrates, thereby avoiding the particular arrangement for placements of both the active device 20 and the passive circuit 10 due to adoption of a certain substrate required by the active device 20, and avoiding an increase of the manufacturing cost due to the passive devices 12 occupying a large area

In this embodiment, the first substrate 11 is made of silicon on insulator (SOI), high resistance Si, GaAs, AlN, ceramic, sapphire, or combinations thereof. The second substrate 21 is made of SiC. The first substrate 11 is made of a material different from a material of the second substrate 21. In this embodiment, when the active device 20 needs to adopt a substrate having a higher cost such as a SiC substrate, only placement of the active device 20 needs to be taken into consideration. In the passive circuit 10, the passive devices 12 may adopt a substrate having a lower cost, thereby avoiding a high cost for manufacturing the microwave integrated circuit.

In this embodiment, the epitaxial layer 22 includes a buffer layer, a gallium nitride layer, and an aluminum gallium nitride layer sequentially disposed in such order in the bottom-top direction.

The wire bonding is only suitable for a low frequency microwave circuit to electrically connect the electrodes 23 to the back side of the active device 20, and will affect efficiency of the microwave integrated circuit using a high frequency microwave circuit. Referring to FIG. 3, in this embodiment, each of the first conductive connectors 240 includes a backside through hole 24 that penetrates the second substrate 21 and the epitaxial layer 22. The backside through holes 24 and the electrodes 23 correspond to each other in position. That is to say, the backside through holes 24 and the electrodes 23 correspond to each other in position in the bottom-top direction. Projections of the backside through holes 24 on an imaginary plane perpendicular to the bottom-top direction overlap projections of the electrodes 23 on the imaginary plane. In addition, each of the first conductive connectors 240 further includes a first conductive metal layer 25 that is formed on a back side of the second substrate 21 and that is formed inside a respective one of the backside through holes 24. The first conductive metal layer 25 contacts a respective one of the electrodes 23.

A side of the first conductive metal layer 25 is connected to the respective one of the electrodes 23, and another side of the first conductive metal layer 25 extends to the back side of the active device 20. By virtue of the first conductive metal layer 25 that is formed on the back side of the second substrate 21 and that is formed inside the respective one of the backside through holes 24, the respective one of the electrodes 23 is connected to a respective one of the reserved pins 13 via the first conductive metal layer 25, thereby connecting the active device 20 to the passive circuit 10.

In some embodiments, a shape of each of the backside through holes 24 is not limited. The shape may have a circular cross section perpendicular to the bottom-top direction, a rectangular cross section, or a cross section of other shapes, as long as the backside through holes 24 may expose the electrodes 23, thereby electrically connecting the electrodes 23 to the back side of the active device 20 via the first conductive metal layers 25.

In some embodiments, the first conductive metal layers 25 may be made of, for example, silver, copper, gold, aluminum, nickel, iron, or other conductive metals, but is not limited thereto, and may be selected according to actual requirements. Since copper is less expensive and may effectively achieve conductive functions, in this embodiment, the first conductive metal layers 25 are made of copper.

In this embodiment, by virtue of the backside through holes 24 and the first conductive metal layers 25, the electrodes 23 are electrically connected to the back side of the active device 20. Due to the back side of the active device 20 being a flat surface, soldering may be easily achieved. In addition, the second substrate 21 of the active device 20 provides sufficient strength, which allows the protective film to be formed on the front side of the active device 20. The first conductive metal layers 25 made of copper may effectively dissipate heat.

In this embodiment, each of the electrodes 23 includes a gate electrode (G) as an input terminal, a source electrode (S) as an ground terminal, and a drain electrode (D) as an output terminal, and each of the reserved pins 13 includes a gate electrode pin, a source electrode pin, and a drain electrode pin. The gate electrode (G) is connected to the gate electrode pin, the source electrode (S) is connected to the source electrode pin, and the drain electrode (D) is connected to the drain electrode pin.

In this embodiment, the electrodes 23 are electrically connected to the back side of the active device 20 via the first conductive metal layers 25 in a spaced-apart manner so as to be electrically isolated from each other. For example, the first conductive metal layers 25 on the back side of the active device 20 may be divided into regions that correspond respectively to the electrodes 23, and the regions are spaced apart from each other. That is to say, the first conductive metal layers 25 that respectively correspond to the electrodes 23 do not contact each other, thereby achieving electrical isolation.

Spacings among the first conductive metal layers 25 on the back side of the active device 20 may be formed at a same time when the first conductive metal layers 25 are formed. For example, a plurality of spacers may be provided when forming the first conductive metal layers 25 so as to respectively form the spacings at the positions of the spacers after the spacers are removed. Alternatively, the first conductive metal layers 25 may be formed first, and then the spacings are formed therein.

Referring to FIG. 2, in this embodiment, the back side of the active device 20 is formed with a plurality of backside cutting channels 26 for electrically isolating the electrodes 23 from each other. The backside cutting channels 26 are formed on the first conductive metal layers 25 at the back side of the active device 20. The backside cutting channels 26 may be formed after forming the first conductive metal layers 25 by photolithography. Depths of the backside cutting channels 26 are same as depths of the first conductive metal layers 25 (i.e., the backside cutting channels 26 penetrate the first conductive metal layers 25).

Each of the backside cutting channels 26 may include a first cutting channel 261 to make the active device 20 electrically isolated. The first cutting channel 261 is located at a periphery of the active device 20 (see the rectangular shape at the edge on the right in FIG. 2). The first cutting channel 261 may have a rectangular shape, a circular shape, etc.

Each of the backside cutting channels 26 may also include a second cutting channel 262 that electrically isolates the electrodes 23 from each other in the active device 20. The second cutting channel 262 is located at a periphery of each of the electrodes 23 (see the small rectangular shape on the right in FIG. 2). The second cutting channel 262 may have a rectangular shape, a circular shape, etc.

In some embodiments, an insulation layer may be formed inside each of the backside through holes 24. The first conductive metal layer 25 may also be formed on the insulation layer inside each of the backside through holes 24. Similarly, the insulation layer and the first conductive metal layer 25 may be sequentially formed on the back side of the active device 20. By virtue of the insulation layer, the electrodes 23 are electrically isolated from each other.

The insulation layer may be formed by deposition, or by applying a layer of an insulating material on the backside through holes 24, such as polyester, polyimide, fluoropolymer, etc.

Referring to FIG. 4, in the passive circuit 10, the base substrate is formed with a plurality of heat dissipating holes 16. In some embodiments, the heat dissipating holes 16 are arranged regularly on the base substrate underneath the gate electrode pins. A shape of each of the heat dissipating holes 16 is not limited. Each of the heat dissipating holes 16 may have a circular cross section or a rectangular cross section. By virtue of forming the heat dissipating holes 16 on the base substrate, heat dissipation of the microwave integrated circuit is improved, thereby improving performance of the microwave integrated circuit.

In this embodiment, the base substrate further includes a plurality of second conductive connectors 140 that correspond in position to the passive devices 12 and the active device 20 for connecting the passive devices 12 and a ground terminal (i.e., the source electrode (S)) of the active device 20 to a back side of the base substrate.

Referring back to FIG. 3, in some embodiments, each of the second conductive connectors 140 includes a back hole 14 that penetrates the base substrate, and a second conductive metal layer 15 that is formed on the back side of the base substrate and inside the back hole 14. The second conductive metal layer 15 of each of the second conductive connectors 140 contacts a respective one of the passive devices 12 and a respective one of the reserved pins 13 that corresponds in position to the ground terminal of the active device 20. Particularly, the second conductive metal layer 15 connected to the source electrode pin of the reserved pins 13 allows connection of the source electrode (S) as the ground terminal of the active device 20 to the back side of the passive circuit 10.

The second conductive metal layers 15 formed inside the back holes 14 and the first conductive metal layers 25 formed inside the backside through holes 24 are made of a same material, and therefore details of the material of the second conductive metal layers 15 are omitted.

In this embodiment, the microwave integrated circuit includes the passive circuit 10 and the active device 20. The passive circuit 10 adopts the first substrate 11, and the active device 20 adopts the second substrate 21. The active device 20 is disposed in the active region 101 of the passive circuit 10, and the passive devices 12 are disposed in the passive region 102 of the passive circuit 10. The electrodes 23 of the active device 20 are electrically connected to the back side of the active device 20 via the first conductive connectors 240, thereby allowing the electrodes 23 to be connected to the reserved pins 13 on the passive circuit 10, so as to connect the back side of the active device 20 to the front side of the passive circuit 10, and the microwave integrated circuit is thus formed.

In the microwave integrated circuit, the active device 20 may be connected to the passive circuit 10 via the first conductive connectors 240. The active device 20 and the passive circuit 10 may adopt different substrates, thereby avoiding the adoption of a certain substrate required by the active device 20 and avoiding the increase of the manufacturing cost.

The disclosure further provides a method for manufacturing the microwave integrated circuit.

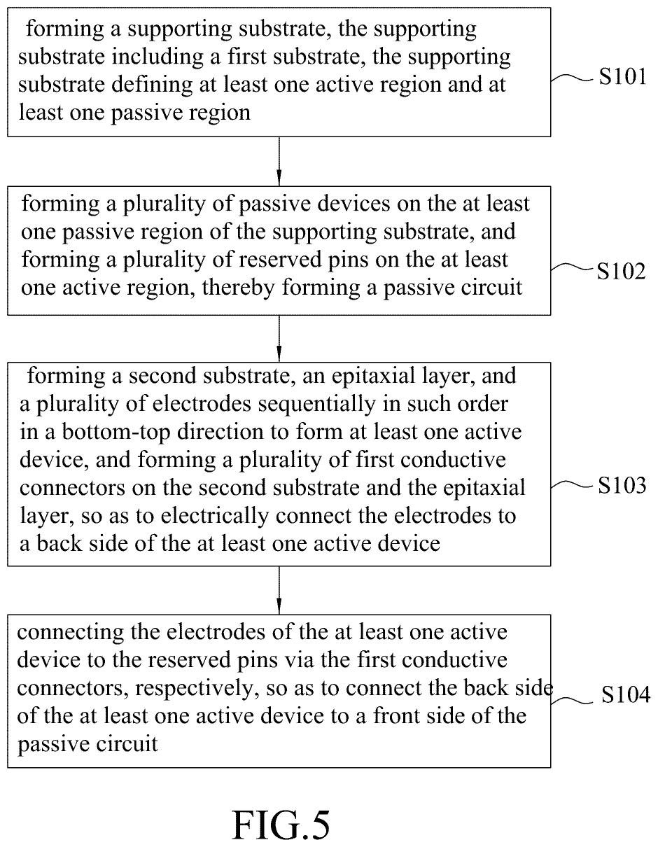

Referring to FIG. 5, a flow chart of the method for manufacturing an embodiment of the microwave integrated circuit is illustrated.

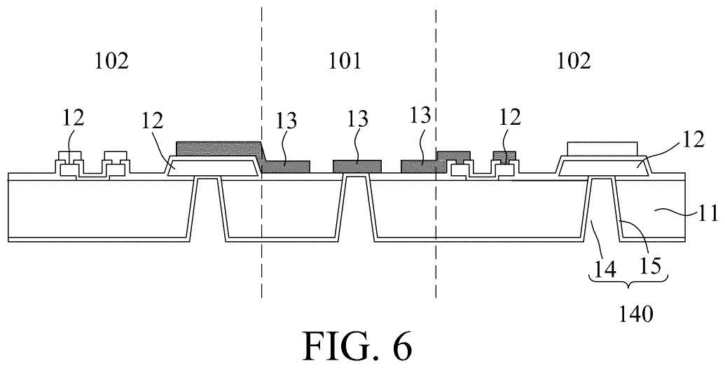

Referring to FIG. 6, in step S101, the base substrate is formed, which includes the first substrate 11 and defines at least one active region 101 and at least one passive region 102.

In this embodiment, the first substrate 11 is made of silicon on insulator (SOI), high resistance Si, GaAs, AlN, ceramic, sapphire, or combinations thereof. The first substrate 11 may further include the epitaxial structure, which is not a focus of the present disclosure, and therefore description thereof is omitted.

In step S102, the passive devices 12 are formed on the passive region 102 of the base substrate, and the reserved pins 13 are formed on the active region 101, thereby forming the passive circuit 10.

In this embodiment, the passive devices 12 include capacitors, inductors, and resistors. Each of the reserved pins 13 in the active region 101 includes the gate electrode pin, the source electrode pin, and the drain electrode pin.

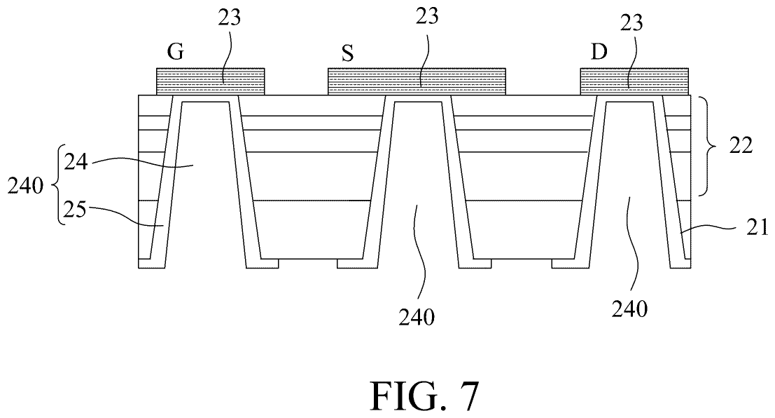

Referring to FIG. 7, in step S103, the active device 20 is formed by forming the second substrate 21, the epitaxial layer 22, and the electrodes 23 sequentially in such order in the bottom-top direction, and disposing the first conductive connectors 204 in the second substrate 21 and the epitaxial layer 22, so as to electrically connect the electrodes 23 to the back side of the active device 20.

In this embodiment, manufacturing of the active device 20 is independent from that of the passive circuit 10. When forming the active device 20, the second substrate 21 is first provided and may be made of SiC. The epitaxial layer 22 is formed on the second substrate 21, and may include a plurality of layers including a buffer layer, a gallium nitride layer, and an aluminum gallium nitride layer sequentially formed in such order in the bottom-top direction.

The epitaxial layer 22 may be formed by a process such as low pressure chemical vapor deposition (LPCVD), plasma enhanced chemical vapor deposition (PECVD), inductively coupled enhanced plasma deposition (ICP-PECVD), etc.

The electrodes 23 are formed on the epitaxial layer 22 away from the second substrate 21. Each of the electrodes 23 includes the gate electrode (G), the source electrode (S), and the drain electrode (D).

The first conductive connectors 240 may be formed on the second substrate 21 and the epitaxial layer 22. In some embodiments, the first conductive connectors 240 are formed by wire bonding or backside copper piping, but is not limited thereto, as long as the electrodes 23 may be electrically connected to the back side of the active device 20 via the first conductive connectors 240.

In step S104, the electrodes 23 of the active device 20 are connected to the reserved pins 13 via the first conductive connectors 240, respectively, so as to electrically connect the back side of the active device 20 to the front side of the passive circuit 10.

After the passive circuit 10 and the active device 20 are formed, the electrodes 23 are connected to the reserved pins 13 via the first conductive connectors 240, respectively, by copper pillar bumping or metal pad bonding, so as obtain a structure as shown in FIG. 3.

Specifically, via the first conductive connectors 240, for each of the electrodes 23, the gate electrode (G) is connected to the gate electrode pin, the source electrode (S) is connected to the source electrode pin, and the drain electrode (D) is connected to the drain electrode pin, thereby electrically connecting the back side of the active device 20 to the front side of the passive circuit 10.

According to the method of manufacturing the microwave integrated circuit, the passive circuit 10 and the active device 20 may be manufactured separately. The passive circuit 10 adopts the first substrate 11, and the active device 20 adopts the second substrate 21. By virtue of the first conductive connectors 240, the electrodes 23 of the active device 20 are respectively connected to the reserved pins 13 of the passive circuit 10, thereby electrically connecting the back side of the active device 20 to the front side of the passive circuit 10, so as to obtain the microwave integrated circuit. In this method, after the passive circuit 10 and the active device 20 are manufactured separately, the passive circuit 10 and the active device 20 may be connected to each other by soldering or bonding, thereby obtaining the microwave integrated circuit having two different substrates and avoiding high costs.

Referring to FIG. 4, in this embodiment, before or after forming of the reserved pins 13 in the active region 101 of the passive circuit 10, the base substrate may be formed with the heat dissipating holes 16. The heat dissipating holes 16 may improve heat dissipation of the microwave integrated circuit more effectively, thereby improving the performance of the microwave integrated circuit.

Referring to FIG. 7, in some embodiments, forming of the first conductive connectors 240 may be achieved as follows.

The backside through holes 24 that penetrate the second substrate 21 and the epitaxial layer 22 are formed. The backside through holes 24 and the electrodes 23 correspond to each other in position. Each of the first conductive connectors 240 further includes the first conductive metal layer 25 that is formed on the back side of the second substrate 21 and that is formed inside the respective one of the backside through holes 24. The first conductive metal layer 25 contacts the respective one of the electrodes 23, thereby electrically connecting the respective one of the electrodes 23 to the back side of the active device 20 via the first conductive metal layer 25.

Referring to FIG. 2, in this embodiment, the back side of the active device 20 includes the backside cutting channels 26. Specifically, the backside cutting channels 26 are formed on the first conductive metal layers 25 for electrically isolating the electrodes 23 from each other.

The backside cutting channels 26 may be formed after forming the first conductive metal layers 25 by photolithography.

In addition, in the abovementioned process of forming the passive circuit 10, the second conductive connectors 140 may be formed on the base substrate. The second conductive connectors 140 correspond in position to the passive devices 12 and the active device 20 for electrically connecting the passive devices 12 and the ground terminal (i.e., the source electrode (S)) of the active device 20 to the back side of the base substrate.

Referring to FIG. 6, in some embodiments, forming of the second conductive connectors 140 involves thinning and etching of the back side of the base substrate so as to obtain the back holes 14. The back holes 14 correspond in position to the passive devices 12 and the reserved pins 13. The second conductive metal layers 15 are formed on the back side of the base substrate and inside the back holes 14. The second conductive metal layers 15 may be connected to the passive devices 12 and the reserved pins 13.

Referring to FIG. 3, the back hole 14 of each of the second conductive connectors 140 may correspond in position to the respective one of the passive devices 12 and the respective one of the reserved pins 13 that corresponds in position to the ground terminal (i.e., the source electrode (S)) of the active device 20, thereby electrically connecting the respective one of the passive devices 12 and the ground terminal of the active device 20 to the back side of the base substrate.

The manufacturing method provided in this embodiment may be used to manufacture the above-mentioned microwave integrated circuit, which has similar characteristics as the microwave integrated circuits of previous embodiments. Details of the microwave integrated circuit of this embodiment are not to be repeated herein.

In summary, according to the disclosure, the microwave integrated circuit includes the base substrate, the passive devices 12, and the passive circuit 10. The base substrate includes the first substrate 11, the passive devices 12 disposed in the active region 101 of the base substrate, and the reserved pins 13 formed in the active region 101. The microwave integrated circuit further includes the active device 20. The active device 20 includes the second substrate 21, the epitaxial layer 22, the electrodes 23, and the backside through holes 24 that penetrate the second substrate 21 and the epitaxial layer 22, that correspond in position to the electrodes 23, and that electrically connect the electrodes 23 to the back side of the active device 20. The electrodes 23 are connected to the reserved pins 13 via the backside through holes 24, respectively, thereby connecting the back side of the active device 20 to the front side of the passive circuit 10. The microwave integrated circuit includes the passive circuit 10 and the active device 20 each made of a different substrate. Therefore, the manufacturing cost of the microwave integrated circuit is not increased drastically due to passive devices 12 of the passive circuit 10 occupying a large space.

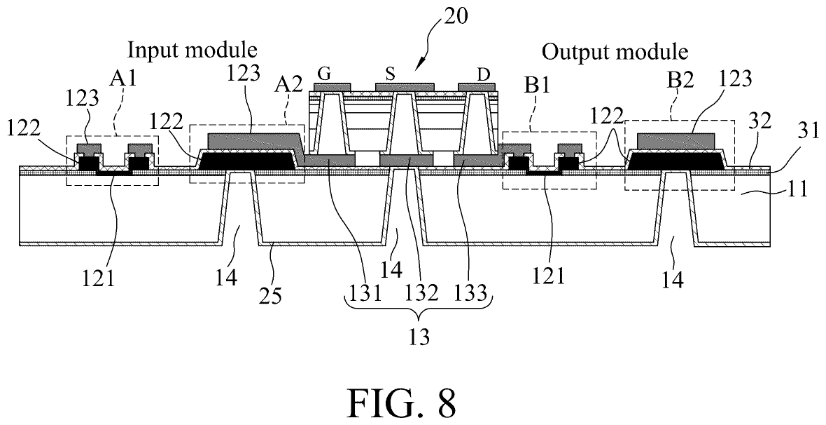

Referring to FIG. 8, a schematic diagram of a second embodiment of the microwave integrated circuit according to the disclosure is shown. The microwave integrated circuit includes an input module, the active device 20, an output module, a first dielectric layer 31, a second dielectric layer 32, a first metal layer 122, a second metal layer 123, and the reserved pins 13. The active device 20 is a gallium nitride device. The input module includes the passive devices 12 which include an input resistor (A1) and an input capacitor (A2). The output module includes the passive devices 12 which include an output resistor (B1) and an output capacitor (B2). The input resistor (A1) includes a thin film resistor layer 121. The first dielectric layer 31 is disposed on the first substrate 11. The first metal layer 122 is disposed on the first dielectric layer 31. Each of the input capacitor (A2) and the output capacitor (B2) includes a lower plate which includes the first metal layer 122. The second dielectric layer 32 serves as a dielectric layer for the input capacitor (A2) and the output capacitor (B2). Each of the input capacitor (A2) and the output capacitor (B2) includes an upper pole layer which includes the second dielectric layer 123. The reserved pins 13 include a gate electrode pin 131 that is electrically connected to the gate electrode (G) of the gallium nitride device via a respective one of the first conductive metal layers 25, a source electrode pin 132 that is electrically connected to the source electrode (S) of the gallium nitride device via a respective one of the first conductive metal layers 25, and a drain electrode pin 133 that is electrically connected to the drain electrode (D) of the gallium nitride device via a respective one of the first conductive metal layers 25. Each of the lower plate of the input capacitor (A2) and the output capacitor (B2) is electrically connected to the source electrode pin 132 via the second conductive metal layers 15 of the back holes 14. Two ends of the input resistor (A1) are conducted out via the first metal layer 122 and the second dielectric layer 123, respectively. The output resistor (B1) includes the thin film resistor layer 121. Two ends of the output resistor (B1) are conducted out via the first metal layer 122 and the second dielectric layer 123, respectively. Each of an end of the input capacitor (A2) and an end of the output capacitor (B2) is electrically connected to the source electrode (S) of the gallium nitride device via the second conductive metal layers 15 of the back holes 14.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A microwave integrated circuit, comprising:
a passive circuit having a front side and including a base substrate and a plurality of passive devices, said base substrate including a first substrate, said base substrate defining at least one active region and at least one passive region, said at least one active region formed with a plurality of reserved pins, said passive devices being disposed on said at least one passive region;
at least one active device having a back side and including a second substrate, an epitaxial layer and a plurality of electrodes disposed sequentially in such order in a bottom-top direction, and a plurality of first conductive connectors disposed in said second substrate and said epitaxial layer, said first conductive connectors corresponding in position to said electrodes for electrically connecting said electrodes to said back side of said at least one active device;
wherein said electrodes are connected to said reserved pins in said at least one active region via said first conductive connectors, respectively, so as to connect said back side of said at least one active device to said front side of said passive circuit.

2. The microwave integrated circuit as claimed in claim 1, wherein each of said first conductive connectors includes a backside through hole that penetrates said second substrate and said epitaxial layer, and a first conductive metal layer that is formed on a back side of said second substrate and inside said backside through hole, said first conductive metal layer contacting a respective one of said electrodes.

3. The microwave integrated circuit as claimed in claim 2, wherein projections of said backside through holes on an imaginary plane perpendicular to the bottom-top direction overlap projections of said electrodes on the imaginary plane.

4. The microwave integrated circuit as claimed in claim 2, wherein said first conductive metal layers are made of copper.

5. The microwave integrated circuit as claimed in claim 2, wherein said electrodes are electrically connected to said back side of said at least one active device via the first conductive metal layers in a spaced-apart manner.

6. The microwave integrated circuit as claimed in claim 5, wherein said first conductive metal layers are divided into regions that correspond respectively to said electrodes, said regions of said first conductive metal layers are spaced apart from each other.

7. The microwave integrated circuit as claimed in claim 2, wherein said back side of said at least one active device is formed with a plurality of backside cutting channels for electrically isolating said electrodes from each other.

8. The microwave integrated circuit as claimed in claim 7, wherein each of said backside cutting channels includes a first cutting channel that makes said at least one active device electrically isolated, and a second cutting channel that electrically isolates said electrodes from each other in said at least one active device.

9. The microwave integrated circuit as claimed in claim 7, wherein depths of said backside cutting channels are same as depths of said conductive metal layers.

10. The microwave integrated circuit as claimed in claim 1, wherein said base substrate is formed with a plurality of heat dissipating holes.

11. The microwave integrated circuit as claimed in claim 1, wherein said first substrate is made of a material different from a material of said second substrate.

12. The microwave integrated circuit as claimed in claim 1, wherein said first substrate is made of silicon on insulator (SOI), high resistance Si, GaAs, AlN, ceramic, sapphire, or combinations thereof.

13. The microwave integrated circuit as claimed in claim 1, wherein said second substrate is made of SiC.

14. The microwave integrated circuit as claimed in claim 2, wherein said electrodes include a ground terminal, and wherein said base substrate further includes a plurality of second conductive connectors that correspond in position to said passive devices and said at least one active device for electrically connecting said passive devices and said ground terminal of said at least one active device to a back side of said base substrate.

15. The microwave integrated circuit as claimed in claim 14, wherein each of said second conductive connectors includes a back hole that penetrates said base substrate, and a second conductive metal layer that is formed on said back side of said base substrate and inside said back hole, said second conductive metal layer contacting a respective one of said passive devices and a respective one of said reserved pins that corresponds in position to said ground terminal of said electrodes.

16. The microwave integrated circuit as claimed in claim 15, wherein said first conductive metal layers and said second conductive metal layers are made of a same material.

17. The microwave integrated circuit as claimed in claim 1, wherein said electrodes include a gate electrode, a source electrode as a ground terminal, and a drain electrode, and said reserved pins includes a gate electrode pin, a source electrode pin, and a drain electrode pin, said gate electrode being connected to said gate electrode pin, said source electrode being connected to said source electrode pin, said drain electrode being connected to said drain electrode pin.

18. A method for manufacturing a microwave integrated circuit, comprising steps of:
forming a base substrate, the base substrate including a first substrate, the base substrate defining at least one active region and at least one passive region;
forming a plurality of passive devices on the at least one passive region (102) of the base substrate, and forming a plurality of reserved pins on the at least one active region, thereby forming a passive circuit;
forming a second substrate, an epitaxial layer, and a plurality of electrodes sequentially in such order in a bottom-top direction to form at least one active device, and forming a plurality of first conductive connectors on the second substrate and the epitaxial layer, so as to electrically connect the electrodes to a back side of the at least one active device; and
connecting the electrodes of the at least one active device to the reserved pins via the first conductive connectors, respectively, so as to connect the back side of the at least one active device to a front side of the passive circuit.

19. The method as claimed in claim 18, wherein the epitaxial layer of the at least one active device includes a plurality of layers including a buffer layer, a gallium nitride layer, and an aluminum gallium nitride layer sequentially formed in such order in the bottom-top direction.

20. The method as claimed in claim 18, wherein the passive circuit and the at least one active device are connected to each other by soldering or bonding.
